(19) United States
(12) Patent Application Publication
(10) Pub. No.: US 2005/0153533 A1
(43) Pub. Date: Jul. 14, 2005

(54) Semiconductor manufacturing method and semiconductor manufacturing apparatus

(75) Inventors: Satohiko Hoshino, Nirasaki-Shi, Yamanashi (JP); Shingo Hishiya, Nirasaki-Shi, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, TOKYO (JP)

(21) Appl. No.: 10/503,131

(22) PCT Filed: Feb. 10, 2003
(86) PCT No.: PCT/JP03/01388

(30) Foreign Application Priority Data
Feb. 12, 2002 (JP) 2002-34182

(51) Int. Cl. H01L 21/4763

(52) U.S. Cl. 438/618

(57) ABSTRACT

Ammonium gas is supplied by means of a gas supply apparatus to a reaction tube containing a semiconductor wafer manufactured with etching and ashing cleaning processing in a predetermined semiconductor manufacturing process, further the reaction tube is heated by a heater, and thus the semiconductor water is made to undergo heating processing in the predetermined ammonium atmosphere. Thereby, relative dielectric constant k value of interlayer dielectric in the semiconductor device, once raised and deteriorated due to the above-mentioned etching and ashing cleaning process or such, is raised and restored.

### TECHNICAL FIELD

The present invention relates to a semiconductor manufacturing method and a semiconductor manufacturing apparatus, and, in particular, to a method of manufacturing a semiconductor device having a multilayer interconnection structure and an apparatus for manufacturing the same.

Along with development of fine structure technology for a semiconductor device, a huge number of semiconductor elements are formed in a substrate in a recent advanced semiconductor integrated (LSI) circuit device. In order to perform interconnection between the semiconductor elements on the substrate in the semiconductor integrated circuit device, a single interconnection layer is not sufficient, and a so-called multilayer interconnection structure is used in which a plurality of interconnection layers are stacked with interlayer dielectrics inserted thereamong. Especially, recently a multilayer interconnection structure produced according to a so-called dual damascene method has been researched in which an interconnection groove and a contact hole are previously formed in an interlayer dielectric corresponding to an interconnection layer, they are filled with by electric conductor, and therewith, the interconnection layer is produced. According to the dual damascene method, it is not necessary to produce an interconnection layer by means of patterning for an electric conductor layer, copper can be used in an interconnection layer which provides a low resistance, superior anti-electron-migration performance and so forth, while, on the other hand, dry-etching was difficult. Thereby, it is possible to reduce signal delay in the multilayer interconnection structure.

### BACKGROUND ART

On the other hand, in a future semiconductor device called deep submicron having a hyperfine structure such that a design rule may be less than 0.13 μm, parasitic capacitance in an interlayer dielectric has become seriously problematic in a multilayer interconnection structure, and therefore, an SiOF film, an inorganic or organic siloxane film, or an organic film, having a relative dielectric constant of less than 4, has been proposed to be applied for an interlayer dielectric in a multilayer interconnection structure, conventionally. Especially, a relative dielectric constant less than 3 can be realized when an inorganic or organic siloxane film, or an organic film is used.

Various forms may be applied for the dual damascene method. FIGS. 1A through 1F show a conventional temporary interconnection producing method for a multilayer interconnection structure according to the Cu dual damascene method.

With reference to FIG. 1A, an Si substrate 110 on which semiconductor elements such as MOS transistors, not shown are formed, is covered by an interlayer dielectric 111 of a CVD-SiO₂ or such and, on the interlayer dielectric 111, an interconnection pattern 112A is produced. The interconnection pattern 112A is embedded in a subsequent interlayer dielectric 112B formed on the interlayer dielectric 111, and an interconnection layer 112 including the interconnection pattern 112A and the interlayer dielectric 112B is covered by an etching stopper film 113 of SiN or such.

The etching stopper film 113 is further covered by an interlayer dielectric 114, and, on the interlayer dielectric 114, further another etching stopper film 115 of SiN or such is formed. The respective interlayer dielectrics are formed by an SOD (spin on dielectrics, one of coating methods) method, or a CVD (chemical vapor deposition) method.

In the example shown, further another etching stopper film 116 is formed on the etching stopper film 115, and further, the interlayer dielectric 116 is covered by a subsequent etching stopper film 117. These etching stopper films 115 and 117 may be called hard masks. The processes shown are described next.

In a process of FIG. 1A, a resist pattern 118 having an opening 118A corresponding to a desired contact hole is formed on the etching stopper film 117 in a photolithography process; the etching stopper film 117 is removed by dry etching with the use of the resist pattern 118 as a mask; after that the resist pattern is removed by ashing cleaning process; and, after that an opening corresponding to the contact hole is formed in the etching stopper film 117.

Then, in a process of FIG. 1B, the interlayer dielectric 116 is made to undergo dry etching according to an RIE method, thus an opening 116A corresponding to the contact hole is formed in the interlayer dielectric 116, and, after that, the resist pattern 118 is removed by an ashing cleaning process.

Further, in a process of FIG. 1C, a resist film 119 is coated on the structure shown in FIG. 1B so as to fill the opening 116A therewith, and then, by patterning thereof by a photolithography method in a process FIG. 1D, a resist opening 119A corresponding to a desired interconnection pattern 119A is formed in the resist film 119. As a result of the opening 119A being formed, the opening 116A formed in the interlayer dielectric is exposed in the resist opening 119A.

In the process of FIG. 1D, the etching stopper film 117 exposed in the resist opening 119A and the etching stopper film 115 exposed on a depth of the opening 116A are removed by dry etching with the use of the resist film 119 as a mask. In a process of FIG. 1E, the interlayer dielectric 116 and the interlayer dielectric 114 are patterned by dry etching in a lump, and after that, the resist film 119 is removed by dry etching in an ashing cleaning process. As a result of the patterning, as shown in FIG. 1E, an opening 116B corresponding to a desired interconnection groove is formed in the interlayer dielectric 116, and also, an opening 114A corresponding to the desired contact hole is formed in the interlayer dielectric 114. The opening 116B is formed to include the opening 116A.

Further, in a process of FIG. 1F, the etching stopper film 113 exposed in the opening 114A is removed by dry etching according to an RIE method so that the interconnection pattern 112A is exposed. After that, a barrier metal (not shown) and a Cu seed layer are formed in the interconnection groove 116A and the opening 114A according to a PVD (physical vapor deposition) method. After that,.a Cu electric conductor film is made to grow by a Cu electrolytic plating method so as to fill them. Further, annealing processing and chemical mechanical polishing (CMP) are performed, and thereby, an interconnection pattern 120 in which a Cu interconnection pattern 112A and the contact hole 114A are connected is obtained. By further repeating these processes, Cu interconnection patterns in a third layer and a fourth layer may be formed.

In such a low dielectric constant multilayer interconnection structure, as the interlayer dielectrics 112, 114 and 116, low dielectric constant coating insulating films such as aromatic insulating films, organic siloxane films, HSQ (hydrogen silsesquioxane) films, MSQ (methyl silsesquioxane) films, or such are used. In such a conventional multilayer interconnection structure employing the low dielectric constant interlayer dielectrics, since a parasitic capacitance of the interconnection is reduced, signal delay problem caused due to such a parasitic capacitance is reduced. However, in a conventional hyperfine structure semiconductor device called deep submicron having a design rule less than 0.10 μm, it is necessary to further lower relative dielectric constants of interlayer dielectrics, and for this purpose, a use of low density interlayer insulating films including a type of films called porous insulting films (porous MSQ films or such) has been researched.

However, in a semiconductor manufacturing process as that described above, processing of etching or ashing cleaning is executed as mentioned above, and, due to influence thereof, a dielectric constant of the above-mentioned interlayer insulating film is raised. Such a tendency occurs remarkably especially in a case of employing a low relative dielectric (low-k) interlayer dielectric such as an interlayer dielectric of an organic silane family (alkoxylane family) or such. Therefore, an effective countermeasure for such a problem is demanded.

### DISCLOSURE OF THE INVENTION

The present invention has an object to provide, in consideration of the above-mentioned problem, a semiconductor manufacturing method and manufacturing apparatus by which, with a relatively simple configuration, a dielectric constant of an interlayer dielectric of a semiconductor device once raised and deteriorated due to etching, ashing cleaning or such can be again lowered for a recovery.

According to the present invention, a step is provided in which, by heating a semiconductor substrate wafer, a relative dielectric constant of an interlayer dielectric once deteriorated due to influence of etching, ashing cleaning process or such in an antecedent semiconductor manufacturing process is again lowered for a recovery. As a result, the once deteriorated (raised) relative dielectric constant of the interlayer dielectric can be effectively restored (lowered) with a relatively simple configuration.

Furthermore, by performing the above-mentioned heating processing in an ammonium (NH₃) atmosphere, it is possible to effectively reduce a processing temperature required for reviving the dielectric constant.

### BRIEF DESCRIPTION OF THE DRAWINGS

Other purposes, features and advantages of the present invention will become more apparent from reading the following detailed description with reference to the drawings attached herewith.

FIGS. 1A through 1F show conventional multilayer interconnection structure creating processes.

FIG. 2 shows an internal configuration diagram of a semiconductor manufacturing apparatus which can carry out a semiconductor manufacturing method according to an embodiment of the present invention.

FIG. 3 shows an experimental result proving a function and an effect of the present invention (#1).

FIG. 4 shows an experimental result proving a function and an effect of the present invention (#2).

FIG. 5 shows an experimental result proving a function and an effect of the present invention (#3).

FIGS. 6A and 6B show an experimental result proving a function and an effect of the present invention (#4).

FIG. 7 shows an internal configuration diagram of a semiconductor manufacturing apparatus in another example which can carry out a semiconductor manufacturing method according to an embodiment of the present invention.

FIG. 8 shows an internal configuration diagram of a semiconductor manufacturing apparatus in further another example which can carry out a semiconductor manufacturing method according to an embodiment of the present invention.

### THE BEST MODE FOR CARRYING OUT THE PRESENT INVENTION

An embodiment of the present invention will be described in detail based on figures.

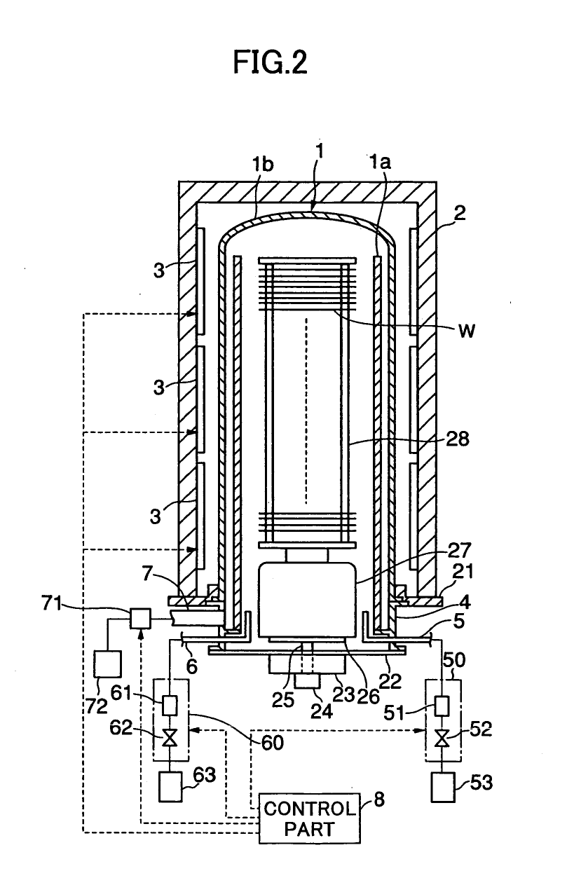

FIG. 2 shows an elevational sectional diagram of a vertical-type thermal processing apparatus used as a semiconductor manufacturing apparatus which can carry out a semiconductor manufacturing method in an embodiment of the present invention. This apparatus includes a reaction tube 1 having a double tube structure made of quartz having an inner tube 1a having both ends opened and an outer tube 1b having an upper end closed. Around the reaction tube 1, a heat insulator 2 is fixed onto a member 21, and, inside the heat insulator 2, a heater 3 which is made of a resistor heating body acts a heating means is provided in a form of being divided vertically into a plurality of divisions (in an example of FIG. 2, it is divided into three stages for convenience).

The inner tube la and the outer tube 1b are supported on a tube-like manifold 4 at lower parts thereof, and, on the manifold 4, a first gas supply pipe 5 and a second gas supply pipe 6 are provided to open supply nozzles in a lower part and inside of the inner tube la. The first gas supply pipe 5 is connected with an ammonium gas supply source 53 via a first gas supply control part (ammonium gas supply control part) 50 including a flow rate control part 51 and a valve 52, while the second gas supply pipe 6 is connected with an steam supply source 63 via a second gas supply control part 60 including a flow rate control part 61 and a valve 62. In this example, an ammonium gas supply part is configured by the first gas supply pipe 5 and the first gas supply control part 50, while a steam supply part is configured by the second gas supply pipe 6 and the second gas supply control part 60.

An evacuate pipe 7 is provided in the manifold 4 for the purpose of evacuation from between the inner tube 1a and the outer tube 1b, and the evacuate pipe 7 is connected with a vacuum pump 72 via a pressure control part 71 including a butterfly valve, for example. In this example, the inner tube 1a, the outer tube 1b and the manifold 7 configure a reaction vessel.

Further, a lid 22 is provided to close a bottom opening of the manifold 4, and the lid 22 is provided on a boat elevator 23. On the lid 22, a rotation table 26 is provided via a rotation shaft 25 rotated by a driving part 24, and, on the rotation table 26, a wafer boat 28 which is a substrate holding device is mounted via a heat insulating unit 27 made of a heat insulting pipe. This wafer boat 18 is configured to hold many semiconductor substrate wafers W in a manner of shelves.

Further, this vertical-type thermal processing apparatus includes a control part 8, which has a function of controlling the heater 3, the pressure control part 71, the first gas supply control part 50 and the second gas supply control part 60 according to a predetermined program stored in a memory which is a part of the control part 8.

Operation of performing thermal processing on semiconductor substrate wafers W with the use of the above-described vertical-type thermal processing apparatus is described next. However, before that, a coated film (interlayer dielectric) provided on a semiconductor substrate is described first. This coated film is produced as a result of a chemical of a polysiloxane family in which a functional group selected from among a methyl group (—CH₃), a phenyl group (—C₆H₅) and a vinyl group (—CH═CH₂) is bonded with a silicon atom, being coated on a substrate, such as a wafer surface, by spin coating, and then being dried.

The polysiloxane is obtained from hydrolyzing a silane compound having a hydrolyzable group under a condition of existence of a catalyst or a condition with no catalyst and condensing it. As the silane compound having a hydrolyzable group, the following can be cited as a preferable example: trimetoxysilane, trietoxysilane, methyltrimetoxysilane, methyltrietoxysilane, methyltri-n-proxysilane, methyltri-iso-propoxysilane, ethyltrimetoxysilane, ethyltrietoxysilane, vinyltrimetoxysilane, vinyltrietoxysilane, phenyltrimetoxysilane, phenyltrietoxysilane, dimethyldimetoxysilane, dimethyldietoxysilane, diethyldimetoxysilane, diethyldietoxysilane, diphenyldimetoxysilane, diphenyldietoxysilane, tetrametoxysilane, tetraetoxysilane, tetra-n-propoxysilane, tetra-iso-propoxysilane, tetra-n-butoxysilane, tetra-sec-butoxysilane, tetra-tert-butoxysilane, tetraphenoxysilane or such.

As the catalyst used in the hydrolysis, acid, chelate compound, alkali, or such can be cited, and, especially, alkali such as ammonium, alkylamine or such is preferable. A molecular weight of the polysiloxane should be, in weight-average molecular weight corrected to polystyrene according to a GPC method, in a range between hundred thousand and ten million, preferably in a range between hundred thousand and nine million, or more preferably in a range between two hundred thousand and eight million. If it is less than fifty thousand, there may be a case where it is not possible to obtain a sufficient dielectric constant and coefficient of elasticity. On the other hand, if it is more than ten million, homogeneity of film coating may be deteriorated.

Further, the chemical of the polysiloxane family should preferably satisfy the following formula:
0.9≧R/Y≧0.2
(R denotes the atomicity of the methyl group, the phenyl group, or the vinyl group in the polysiloxane, and Y denotes the atomicity of Si)

The chemical (coating liquid) of polysiloxane family is one in which the above-mentioned polysiloxane is dissolved in an organic solvent, and, as a specific example of a catalyst used in this case, at least one selected from among a group of an alcohol solvent, a ketone solvent, an amid solvent and an ester solvent can be cited. To this coating liquid, other than polysiloxane, any other constituent such as a surface active agent, a heat decomposable polymer or such may be added if necessary.

For example, the 150 semiconductor wafers W on which the coated films are formed as described above are held by the wafer boat 28 in a manner of selves, are lifted by the elevator 23, and are brought into the reaction vessel including the reaction tube 1 and the manifold 4. The inside of the reaction vessel is previously kept for example at a process temperature for thermal processing which will be performed, and then is lowered as a result of the wafer boat 28 being thus brought therein. Therefore, it stands for a predetermined duration until the process temperature is stabilized. The process temperature is a temperature of a zone in which the semiconductor wafers which are products are placed, and is set in a range between 300 and 400° C., more preferably in a range between 300 and 380° C. Further, until the temperature inside the reaction vessel is stabilized at the process temperature, the pressure inside of the reaction vessel is reduced into a vacuum and a predetermined pressured reduced atmosphere is provided by means of the pressure control part 71.

After the inside of the reaction vessel thus comes to have the predetermined pressure reduced atmosphere stably, ammonium gas is supplied to the reaction vessel with a flow rate thereof controlled to have a predetermined value by means of the flow rate control part 51 via the gas supply control part 50, i.e., with the valve 52 opened. Furthermore, through the second gas supply control part 60, i.e., with the valve 62 opened, steam is supplied to the reaction vessel with a flow rate thereof controlled to have a predetermined value by means of the flow rate control part 61. Under this condition, the coated films are burned (thermal processing and curing). After the thermal processing is thus performed for a predetermined duration, nitrogen gas, for example, is supplied from an inactive gas supply pipe (not shown), and thereby, the inside of the reaction vessel is returned to the atmospheric pressure. After that, the lid 22 is lowered, and the wafer boat 28 is carried out. Such a series of operations are controlled according to the predetermined program by the control part 8.

In the above-described thermal processing, it is expected that, NH₄⁺ and OH⁻ are generated as a result of reaction occurring between a minute amount of water (H₂O) and ammonium (NH₃) existing in the reaction vessel, these NH₄⁺ and OH⁻ as well as not-yet reacting H₂O act as catalysts for generating reaction between (—SiOH) in the coated films expressed by the following formula so as to cause dehydration condensation polymerization reaction and generate —Si—O—Si—:
—SiOH+HOSi—→—Si—O—Si—

As the flow rate of the ammonium gas, a range between 0.01 slm and 5 slm is preferable in a case where the wafer boat 28 having a maximum permissible mounting number of 170 wafers (including dummy wafers at the top and bottom thereof) is filled with the 8-inch wafers W, and the processing is performed thereon. Especially, a range between 0.1 slm and 2 slm is preferable. As to the flow rate of the steam, a flow rate corrected to liquid in a range between 0.005 sccm and 3 sccm with respect to 0.1 slm of the ammonium gas is preferable. As to the pressure inside of the reaction vessel, influence of the pressure on the dielectric constant of the interlayer dielectric was studied while the pressure was changed in a range between 0.16 kPa and 90 kPa. As a result, there was no substantial change in the dielectric constant due to the change in the pressure, and accordingly, it can be understood that any one of a reduced pressure atmosphere, a normal pressure atmosphere, and a pressurized atmosphere may be applied.

Inactive gas such as nitrogen gas may be supplied simultaneously with the supply of the ammonium gas into the reaction vessel. This is advantageous for controlling oxidizing atmosphere so as to control oxidization of the coated films, and to avoid adverse influence of the oxidization atmosphere in a case where oxidizing constituents such as oxygen may be left much in the reaction vessel. However, there is no problem without supply of inactive gas simultaneously along with the supply of the ammonium gas on an experimental basis, and thus, the supply of inactive gas is not an absolute requirement. The duration of the thermal processing should be not less than ten minutes under the temperature of 350° C., for example. On the other hand, when this duration is too long, there occurs a concern for an adverse influence of a thermal history left in lower ones of the films. Accordingly, the duration is preferably within 60 minutes.

According to the above-described embodiment, since ammonium and moisture (steam supplied to the reaction vessel or moisture left in the reaction vessel) act as catalysts when the coated films of polysiloxane family are burned to form the interlayer dielectrics, it is possible to reduce activation energy required for the burning reaction. As a result, even when the thermal processing temperature is low, or even when the thermal processing duration (burning duration) is short, the burning reaction satisfactorily makes progress, and thus, it is possible to relatively easily obtain the interlayer dielectrics having low dielectric constants. Accordingly, it is possible to obtain physical properties in the interlayer dielectrics required for, for example, a dual damascene structure in a device in such a generation that a line width becomes 0.10 μm. Also, there is no possibility of adverse influence of heat on a device structure already produced. Although the double tube structure is applied in the above-described vertical-type thermal processing apparatus, it is also possible to apply a single-tube-type reaction tube having a configuration in which evacuation is performed from the top.

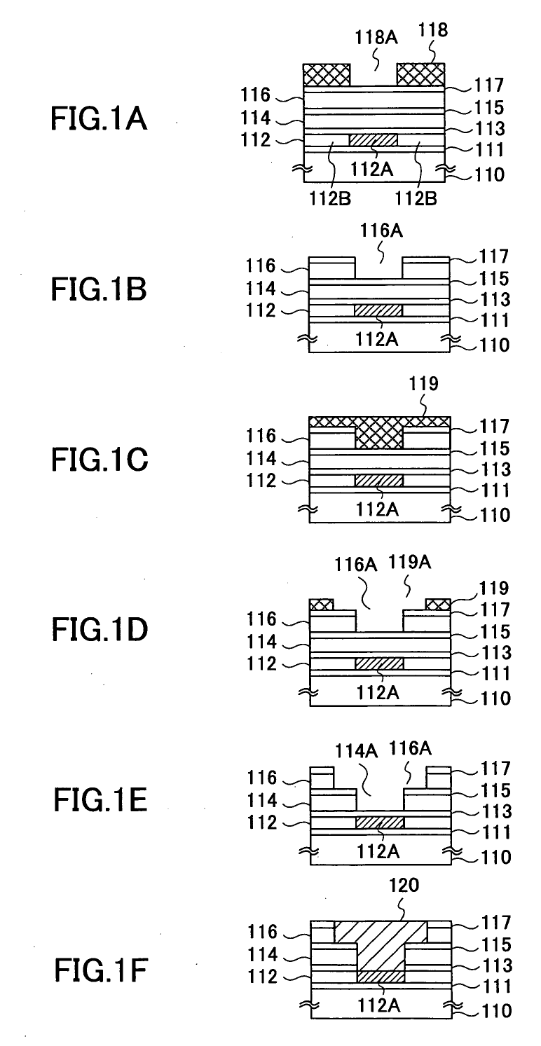

In the above, the method of coating and burning of the interlayer dielectrics has been described. By applying such a method to a semiconductor manufacturing process such as that described with reference to FIGS. 1A through 1F, it is possible to carry out interlayer dielectric burning processing in a semiconductor device. In such a semiconductor manufacturing process, as described above with reference to FIGS. 1A through 1F, etching and ashing cleaning processes or such is performed, and, due to its influence, increase in relative dielectric constants of interlayer dielectrics occurs as described above. In order to lower the once raised relative dielectric constants of the interlayer dielectrics again for a recovery, interlayer dielectric relative dielectric constant recovery processing is performed according to one embodiment of the present invention as described next.

In the interlayer dielectric relative dielectric constant recovery processing, by keeping a semiconductor device once manufactured in a semiconductor manufacturing process such as that mentioned above, in an atmosphere at a predetermined ambient temperature for a predetermined duration, again lowering the once raised relative dielectric constants of the interlayer dielectrics is made to occur. Specifically, as the above-mentioned predetermined ambient temperature, a range between 200° C. and 450° C. (preferably 400° C.) is applied, and also, the semiconductor substrates are held in an N₂ atmosphere. A duration of holding them is on the order of 30 minutes when the ambient temperature is approximately 400° C.

Such interlayer dielectric relative dielectric constant recovery processing can be performed in the above-mentioned vertical-type thermal processing apparatus shown in FIG. 2. Specifically, with the use of the above-mentioned heater 3, the control part 8 and so forth, the processing can be carried out similar to the interlayer dielectric burning processing described above. Especially, since a so-called batch furnace having a structure such as the above-described vertical-type thermal processing apparatus is suitable for thermal processing for a relatively long duration, it is possible to use such equipment to easily carry out the interlayer dielectric relative dielectric constant recovery processing according to the present invention. By means of such interlayer dielectric relative dielectric constant recovery processing (thermal processing), it is possible to effectively lower, for a recovery, relative dielectric constants (so-called k values) of low dielectric constant interlayer dielectrics (so-called low-k films) once raised and deteriorated due to etching, ashing processing or such in a semiconductor manufacturing process.

As disclosed in Japanese Laid-open Patent Application No. 2001-266019, which is a prior application of the present applicant and so forth, it has been proved that, by performing interlayer dielectric burning processing (so-called curing processing) such as that described above in an ammonium atmosphere, it is possible to effectively lower a processing temperature required for the burning processing. This principle can be applied to interlayer dielectric relative dielectric constant recovery processing (k value recovery processing) according to the present invention. That is, by performing the interlayer dielectric relative dielectric constant recovery processing (i.e., k value recovery processing) also in an ammonium atmosphere, it is expected that a required processing temperature can be effectively lowered the same as in the above-mentioned case of curing processing.

Specifically, in k value recovery processing according to the present invention, although thermal processing on the order of 400° C. is required in N₂ atmosphere, it is expected that the same k value recovery effect can be obtained from thermal processing even at a lower temperature. Such k value recovery processing in an ammonium atmosphere is also achievable, for example, with the use of the vertical-type thermal processing apparatus described above with reference to FIG. 2 in the same manner as that described above. In this case, it is possible to carry out the same by creating a desired ammonium atmosphere by applying the first gas supply control part 50, the control part 8 and so forth in the same apparatus.

An experimental result concerning the above-mentioned k value recovery processing according to the present invention is described next.

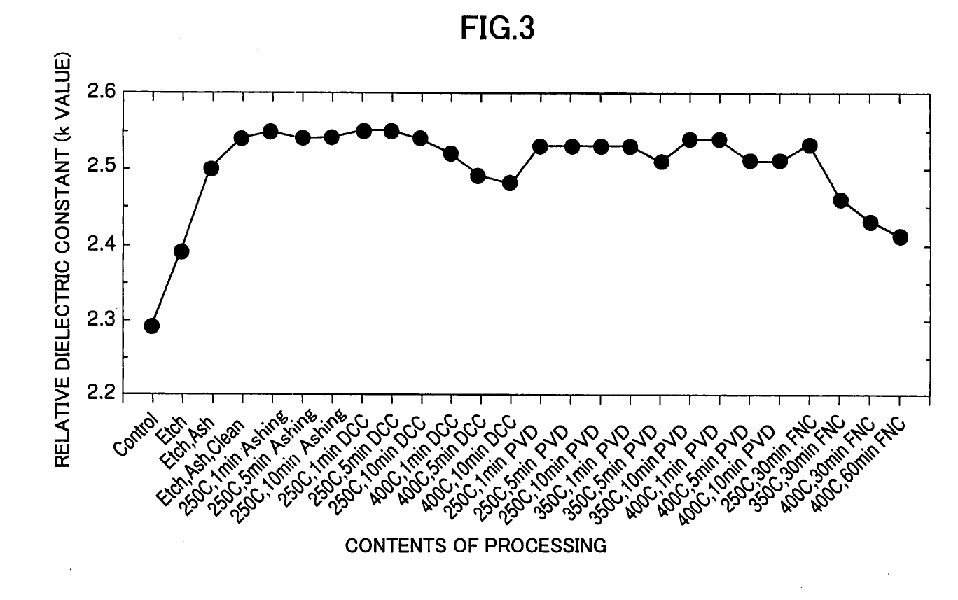

FIG. 3 shows a state in which a k value in an interlayer dielectric increases and deteriorates due to etching, ashing processing or such performed on a semiconductor device including the interlayer dielectric, and a state in which the k value recovers in a case where thermal processing (i.e., interlayer dielectric relative dielectric constant recovery processing according to the present invention) was performed under various conditions on the interlayer dielectric in which the k value is once raised and deteriorated. In the figure, the meaning of each symbol indicating a processing condition is as follows:
Etch: etching processing;
Ash: ashing processing;
Clean: cleaning processing;
C: ° C.;
min: minutes;
Ashing: thermal processing (p=100 mTorrs) with the use of an ashing processing apparatus (asher);
DCC: thermal processing (p=atom (atmospheric pressure)) with the use of a burning processing apparatus (hot plate);
PVD: thermal processing (p<5×10⁻⁸ Torrs) with the use of a PVD processing apparatus;
FNC: thermal processing with the use of a batch furnace (for example, the apparatus shown in FIG. 2).

It can be seen from this experimentation that it is possible to lower for a recovery a k value once deteriorated and raised up to more than 2.5 then into the order of 2.4 by means of thermal processing especially with the use of the batch furnace (FNC) at 400° C. for more than 30 minutes.

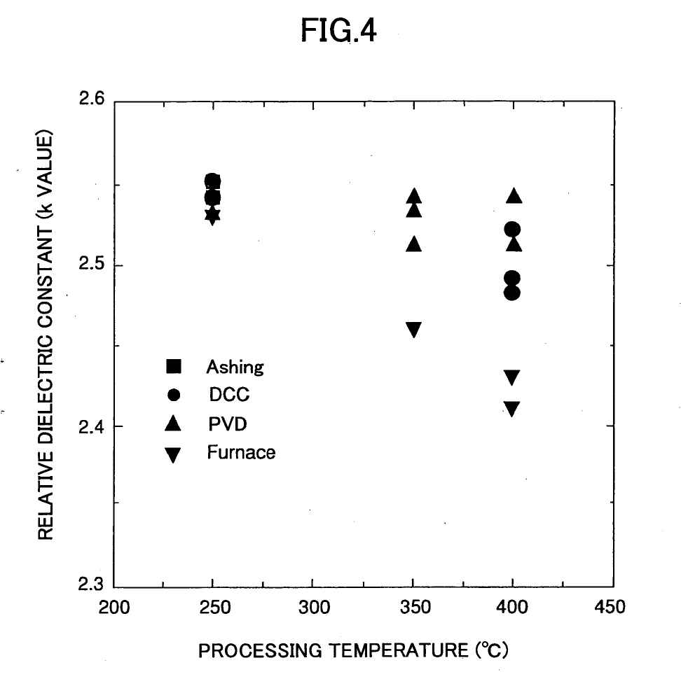

FIG. 4 shows the above-mentioned experimental result through rearrangement with the horizontal axis indicating the processing temperature. From this graph, it can be seen that especially by means of the thermal processing with the use of the batch furnace on the order of 400° C., the k value recovers to the order of 2.4.

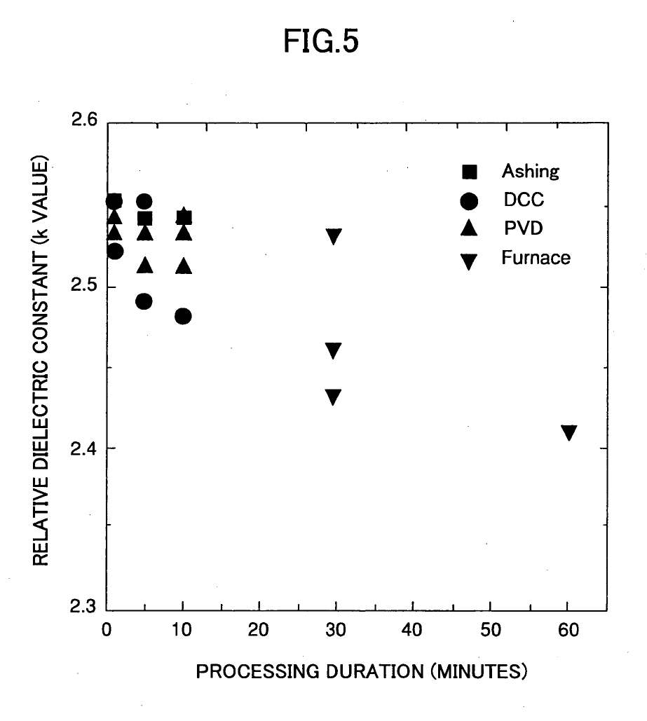

FIG. 5 shows the same with the horizontal axis indicating the processing duration. From the figure, it can be seen that the duration of the thermal processing in a range between 30 minutes and 60 minutes is effective.

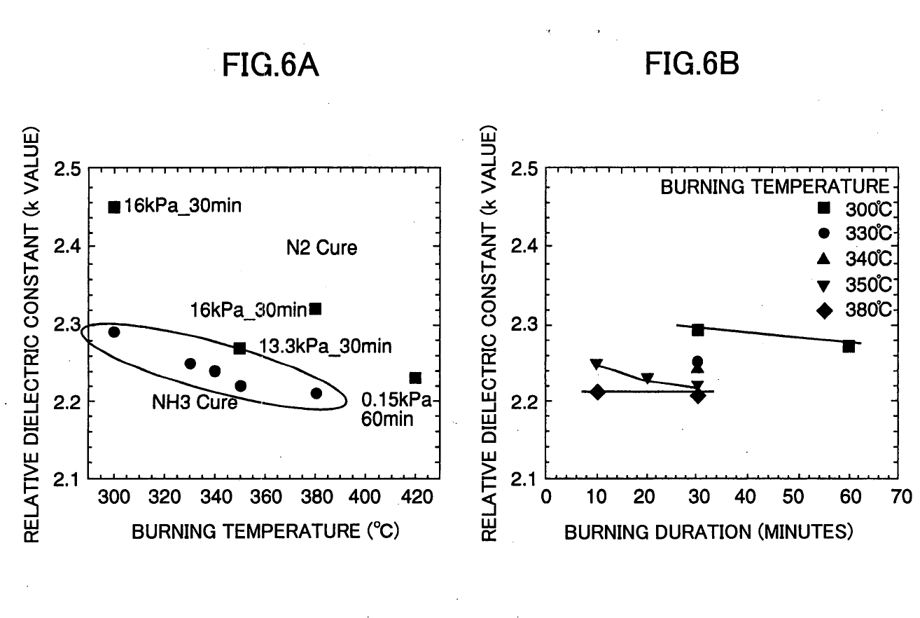

FIGS. 6A and 6B show an experimental result concerning burning (curing) processing in an atmosphere of ammonium NH₃. FIG. 6A shows a comparison between a case where burning is performed in a nitrogen (N₂) atmosphere and a case where burning is performed in an ammonium (NH₃) atmosphere (enclosed by an ellipse). From this graph, it can be seen that by performing burning in an ammonium atmosphere, as mentioned above, it is possible to effectively lower a relative dielectric constant by thermal processing at a relatively low temperature in comparison with a case where it is performed in a N₂ atmosphere.

FIG. 6B shows a difference in k value lowering effect with respect to a burning duration in a case where burning processing is performed in an ammonium atmosphere. From this graph, it can be seen that it is possible to effectively lower a k value by performing burning processing, for example, for 30 minutes at a processing temperature of 350° C. in an ammonium atmosphere. Further, it is seen that, the same k value lowering effect obtained from burning processing for 60 minutes at 420° C. in a nitrogen atmosphere can be obtained from burning processing in an ammonium atmosphere in a processing condition of 350° C. for 30 minutes or 380° C. for 10 minutes. The experimental conditions were as follows:

In the case of burning in an ammonium atmosphere:
Pressure: 13.3 kPa; N₂ flow rate: 10 slm; and NH₃ flow rate: 2 slm.

In the case of burning in a nitrogen atmosphere:
N₂ flow rate: 10 slm

The reason why it is desired that a processing temperature required in heating processing should be lowered in the above-mentioned burning of interlayer dielectrics or in k value recovery processing according to the present invention is as follows: That is, especially in a case of a semiconductor device applying Cu interconnection, physical properties deteriorate in copper which forms an interconnection structure in the semiconductor device due to a diffusion phenomenon, and thereby, there is a possibility that a transistor element or such of the semiconductor device is destroyed in some cases. In order to avoid such a situation, it is desired to lower the semiconductor processing temperature as much as possible so as to control generation of useless diffusion phenomenon in Cu interconnection. Specifically, it is desired that thermal processing should be performed below 400° C.

As a specially effective material for applying the present invention, a material can be cited which has originally a low relative dielectric constant, and also, has the relative dielectric constant remarkably raised and deteriorated due to an influence of etching, ashing cleaning or such in a semiconductor manufacturing process. Specifically, so-called porous MSQ (methyl-silsesquioxane), other MSQ, organic or inorganic low dielectric constant materials for various types of spin on, or the like can be cited. Other then the method with spin on coating, the interlayer dielectric can be created also from a CVD method for example.

As described above, in a case of performing interlayer dielectric relative dielectric constant recovery processing, i.e., k value recovery processing according to the present invention accompanying thermal processing at relatively a high temperature for a long time (for example, 400° C. for 30 minutes or such), the above-mentioned batch furnace (for example, the configuration shown in FIG. 2) is optimum. On the other hand, for example, as described above, by applying a method of performing the k value recovery processing in an ammonium atmosphere as described above or such, it is expected that the processing can be carried out even relatively at a low temperature or for a short duration. In consideration of such a situation, it is expected that, interlayer dielectric relative dielectric constant recovery processing according to the present invention may be sufficiently applicable also for a semiconductor manufacturing process employing another apparatus configuration, for example, a so-called hot plate which is a single wafer type semiconductor manufacturing apparatus, a vacuum processing apparatus (a PVD processing apparatus, a plasma sputter etching apparatus or such) or such.

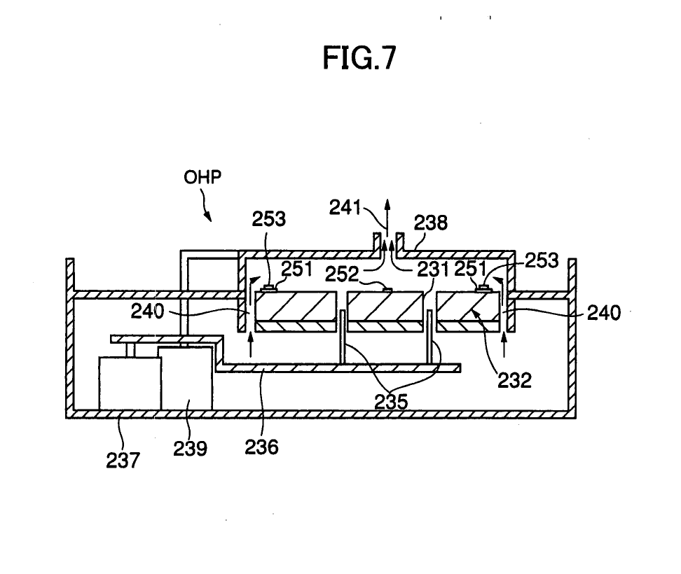

FIG. 7 shows one example of a hot plate type thermal processing apparatus to which the present invention can be applied. The figure shows in particular an elevational sectional view of a low oxygen high temperature heating processing station (OHP) included in an insulating film production apparatus (see Japanese Laid-open Patent Application No. 2001-93899). At an approximately center of this low oxygen high temperature heating processing station (OHP), a hot plate 232 used as a plate to perform heating processing on a wafer W is disposed. Inside of the hot plate 232, a heater (not shown) is embedded.

Several, for example, three through holes 234 are provided between an obverse side and a reverse side of the hot plate 232. In the respective ones of these through holes 234, a plurality of, for example, three supporting pins 235 for transferring the wafer W are removably inserted. These supporting pins 235 are integrally bonded to a bonding member 236 disposed on the side of the reverse side of the hot plate 232. The bonding member 236 is connected with a lifting/lowering cylinder 237 disposed on the side of the reverse side of the hot plate 232. By means of lifting and lowering operation of the lifting/lowering cylinder 237, the supporting pins 235 project from or retreats in the obverse side of the hot plate 232.

Above the hot plate 232, a lifting/lowering cover 238 is disposed. This lifting/lowering cover 238 is liftable and lowerable by the lifting/lowering cylinder 239. When the lifting/lowering cover is lowered as shown, a sealed space for performing heating processing is created between the lifting/lowering cover 238 and the hot plate 232.

Further, as a result of N₂ gas being discharged uniformly from holes 240 in the periphery of the hot plate 232 and also it being evacuated from an evaluate hole 242 at the center of the lifting/lowering cover 238, high temperature heating processing in a low oxygen atmosphere is enabled.

In the above-mentioned thermal processing apparatus, it is possible to carry out k value recovery processing according to the present invention, i.e., interlayer dielectric relative dielectric constant recovery processing according to the present invention by performing thermal processing as described above. Although the example of performing processing with a supply of N₂ gas has been described above, it is expected that the k value recovery effect can be obtained at a relatively low temperature with a supply of NH₃ gas instead.

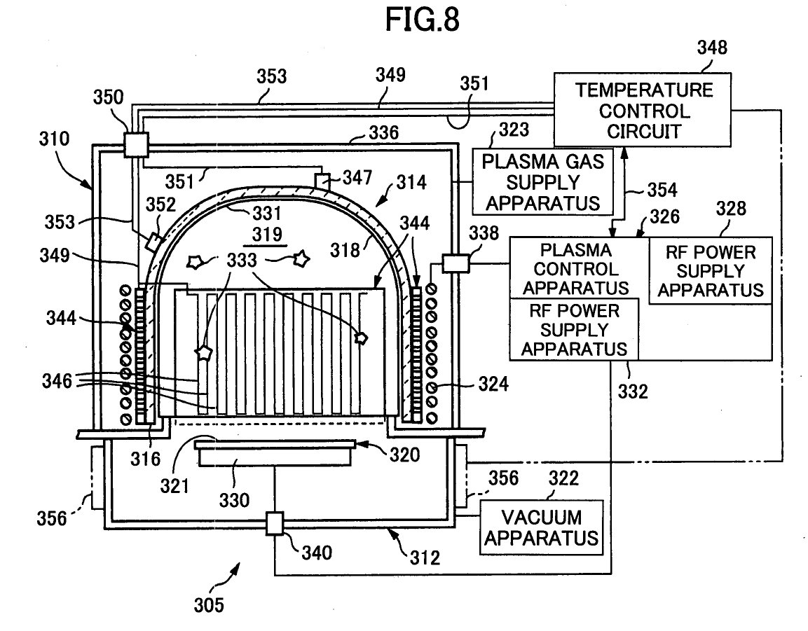

FIG. 8 shows an elevational sectional view of a plasma sputter etching apparatus as one example of a vacuum processing apparatus to which k value recovery processing according to the present invention is applicable (see U.S. Pat. No. 5,589,041). This apparatus 305 includes a plasma processing apparatus 310 including a base 312 and a cover 314. The base 312 and the cover 314 are connected together via a vacuum seal, and provide a sealed processing space 319 accommodating a semiconductor wafer 320 on which plasma sputtering processing is performed. The base 312 is coupled with a vacuum apparatus 322, whereby the sealed processing space is evacuated, and thereby, control is made for a desired processing pressure.

Further, plasma gas is introduced into the processing space 319 by means of a plasma gas supply apparatus 354. The processing space 319 is enclosed by an induction coil 324 for generating excitation plasma gas. The coil 324 is connected with a plasma control circuit 326 including an RF power source 28 normally having an operation range between 0.1 and 27 MHz. The to-be-processed substrate (wafer) 320 is supported by a supporting table 330. The supporting table 330 functions as an electrode, and is connected to the plasma control circuit 326. Further, it is connected with an RF power source 332 normally having an operation range between 0.1 and 100 MHz.

Further, this apparatus 305 is provided with a foil heater 344 for heating the cover 314. The foil heater 344 has a shape like a coil. The foil heater 344 is connected with a temperature control circuit 348. The temperature control circuit 348 controls a temperature of the cover 314 at a desired temperature by turning on/off the foil coil 344, and thereby controls a temperature in the processing space 319. For this purpose, a temperature sensor 347 is provided in the cover 314, and is connected to the temperature control circuit 348. By this control system, the temperature in the processing space 319 can be controlled at a temperature suitable for plasma etching.

Also in this plasma processing apparatus, by performing temperature control of the processing space 319 with the use of the above-mentioned foil heater 344, it is possible to perform thermal processing of the semiconductor substrate 320. Thereby, it is possible to perform k value recovery thermal processing according to the present invention. Also in this case, by supplying NH3 gas, it is possible to obtain the k value recovery effect at a relatively low temperature.

The present invention is applicable not only to the above-mentioned respective embodiments, but also widely to semiconductor manufacturing apparatuses which have functions of performing heating processing on semiconductor substrate wafers.

As described above, according to the present invention, for a relative dielectric constant (k value) of a low dielectric constant (low-k) interlayer dielectric for which further lowering is desired for the purpose of achieving a fine rule in a semiconductor device, even when it is once deteriorated by an influence of etching, ashing cleaning processing or such in a semiconductor manufacturing process, it can be restored with a relatively simple configuration. As a result, it is possible to effectively promote achievement of a fine structure and a highly densified structure in an LSI.

According to the present invention, not only the above-described embodiments, but also other various embodiments can be devised applying a basic concept of the present invention,

Japanese Patent Application No. 2002-34182 (filed on Feb. 12, 2002) which is a basic application of the present invention is herewith incorporated by reference.

1. A semiconductor manufacturing method for manufacturing a semiconductor device having an interconnection structure with insulation by means of an insulating film, comprising the step of:
lowering and to restoring a dielectric constant of the insulting film, once raised and deteriorated in a predetermined semiconductor manufacturing process, by means of heating processing performed in a predetermined atmosphere at least containing ammonium.

2. The semiconductor manufacturing method as claimed in claim 1, wherein:
a processing temperature of the heating processing is in a range between 200° C. and 400° C.

3. The semiconductor manufacturing method as claimed in claim 2, wherein:
a heating duration in the heating processing is approximately 30 minutes when the processing temperature is approximately 400° C.

4. (canceled)

5. The semiconductor manufacturing method as claimed in claim 1, wherein:
said atmosphere containing ammonium further contains steam.

6. The semiconductor manufacturing method as claimed in claim 5, wherein:
said atmosphere containing ammonium and steam has a flow rate of the ammonium in a range between 0.01 slm and 5 slm; and
a flow rate of the steam is in a range between 0.005 and 3 sccm with respect to 0.1 slm of the ammonium.

7. The semiconductor manufacturing method as claimed in claim 1, wherein:
said insulating film comprises an organic interlayer dielectric.

8. The semiconductor manufacturing method as claimed in claim 1, wherein:
said insulating film comprises any one of porous MSQ and other MSQ.

9. The semiconductor manufacturing method as claimed in claim 1 for manufacturing a semiconductor device in which copper is used as interconnection material therein.

10. The semiconductor manufacturing method as claimed in claim 9, wherein:
a Cu dual damascene method is applied as a method of creating interconnection in a semiconductor device having an interconnection structure with the use of copper interconnection material.

11. The semiconductor manufacturing method as claimed in claim 1, wherein:
said predetermined process which raises and deteriorates the relative dielectric constant of the insulating film comprises at least one of etching and ashing cleaning processing.

12. An apparatus for manufacturing a semiconductor device having an interconnection structure, comprising a heating means heating a semiconductor substrate,
wherein said apparatus carries out the method claimed in claim 1 with the use of said heating means.

13. The semiconductor manufacturing apparatus as claimed in claim 12 comprising a batch-type apparatus which can process a plurality of semiconductor substrates simultaneously.

14. The semiconductor manufacturing apparatus as claimed in claim 12, comprising a single wafer type apparatus which processes a semiconductor substrate one by one.

15. The semiconductor manufacturing method as claimed in claim 2, wherein:
said atmosphere containing ammonium further contains steam.

16. The semiconductor manufacturing method as claimed in claim 3, wherein:
said atmosphere containing ammonium further contains steam.

17. The semiconductor manufacturing method as claimed in claim 2, wherein:
said insulating film comprises an organic interlayer dielectric.

18. The semiconductor manufacturing method as claimed in claim 3, wherein:
said insulating film comprises an organic interlayer dielectric.

19. The semiconductor manufacturing method as claimed in claim 2, wherein:
said insulating film comprises any one of porous MSQ and other MSQ.

20. The semiconductor manufacturing method as claimed in claim 3, wherein:
said insulating film comprises any one of porous MSQ and other MSQ.

21. The semiconductor manufacturing method as claimed in claim 2 for manufacturing a semiconductor device in which copper is used as interconnection material therein.

22. The semiconductor manufacturing method as claimed in claim 3 for manufacturing a semiconductor device in which copper is used as interconnection material therein.

23. The semiconductor manufacturing method as claimed in claim 2, wherein:
said predetermined process which raises and deteriorates the relative dielectric constant of the insulating film comprises at least one of etching and ashing cleaning processing.

24. The semiconductor manufacturing method as claimed in claim 3, wherein:
said predetermined process which raises and deteriorates the relative dielectric constant of the insulating film comprises at least one of etching and ashing cleaning processing.

25. An apparatus for manufacturing a semiconductor device having an interconnection structure, comprising a heating means heating a semiconductor substrate,
wherein said apparatus carries out the method claimed in claim 2 with the use of said heating means.

26. An apparatus for manufacturing a semiconductor device having an interconnection structure, comprising a heating means heating a semiconductor substrate,
wherein said apparatus carries out the method claimed in claim 3 with the use of said heating means.
